(19) United States
(12) Patent Application Publication
(10) Pub. No.: US 2014/0091800 A1
(43) Pub. Date: Apr. 3, 2014

(54) NMR SAMPLE CONTAINMENT

(71) Applicant: SCHLUMBERGER TECHNOLOGY CORPORATION, Sugar Land, TX (US)

(72) Inventor: EDMUND J. FORDHAM, CAMBRIDGE (GB)

(73) Assignee: SCHLUMBERGER TECHNOLOGY CORPORATION, Sugar Land, TX (US)

(21) Appl. No.: 14/038,372

(22) Filed: Sep. 26, 2013

(30) Foreign Application Priority Data
Sep. 28, 2012 (GB) 1217375.3

(51) Int. Cl. G01R 33/30

(52) U.S. Cl. CPC G01R 33/305
USPC 324/321

(57) ABSTRACT

Nuclear magnetic resonance spectrometer for examination of a sample under pressure has a coolant vessel containing a radio-frequency coil cooled by coolant in the vessel while located within the magnetic field of the spectrometer. A pressurizable sample holder comprises a nonmagnetic pressure retaining tube formed of electrically insulating matrix material containing electrically insulating reinforcing filaments. The spectrometer is configured to accommodate this sample holder with the axis of the pressure retaining tube transverse to the magnetic field, and the radiofrequency coil at the exterior of the pressure retaining tube. Cooling of the coil improves the signal to noise ratio and offsets the low coil filling factor which is a consequence of placing the coil outside a non-metallic pressure retaining tube. End pieces at each end of the tube are connected together and contain longitudinal pressure stress.

### CROSS-REFERENCE TO RELATED APPLICATION

This application claims priority to British Application No. GB1217375.3 filed 28 Sep. 2012, which is incorporated herein by reference in its entirety.

### BACKGROUND

One technology for examining properties of a solid or liquid sample is nuclear magnetic resonance (NMR) also referred to as magnetic resonance imaging (MRI). There are circumstances where a sample is examined under pressure, thus requiring a sample holder which can contain the sample under pressure while it is in the magnetic field of an NMR spectrometer.

A category of samples for which examination under pressure may be required is solid and also liquid samples collected below ground. When drilling through underground rock, it is common practice to drill around a cylinder of rock, referred to as a rock core, which is subsequently brought to the surface. At the surface, rock samples from such a core may be subjected to various measurements and tests. These samples are usually cylindrical and may be referred to as a core plug. Tests which have been carried out include examination by nuclear magnetic resonance (NMR) also referred to as magnetic resonance imaging (MRI) which entails placing the core within a magnetic field and using one or more radio-frequency coils to apply radio-frequency energy to the core and receive radio-frequency signals from it.

The subterranean rock formations from which such cores are taken are of course at high pressure and it can be desirable to carry out NMR measurements while the sample is under pressure. Liquid samples brought to the surface may also be subjected to NMR measurements whilst still under pressure.

Design of a sample holder which can retain pressure and which can be placed in the magnetic field of an NMR spectrometer needs to address several issues, including mechanical construction for containing pressure, choice of materials to enable the core to be exposed to both magnetic field and radio-frequency, and positioning of the core holder in relation to the functional components (i.e., magnets and coils) of an NMR spectrometer. One issue is the extent to which the cross-section within the radio-frequency coil or coils is occupied by the sample. Signal to noise ratio is better if the sample occupies a high proportion of the cross-section within the coil(s). This is referred to as a high coil filling factor.

There are existing designs of sample holder to contain a sample under pressure. For instance a pressurizable sample holder which is available from Ergotech Ltd, Conwy, Wales uses a tube of glass fiber reinforced composite to contain a rock sample under pressure. Compressive force applied to the ends of the tube opposes stress longitudinally relative to the pressurized tube. The radio-frequency coil and the magnets of an NMR spectrometer are positioned outside the tube in spaces between the tube and tie rods connecting the structural parts which apply compressive force to the ends of the tube. In this arrangement, where the magnets fit between the tube and the tie rods, the tie rods are spaced apart in the direction of the magnetic field and the spacing between them has to be greater than the distance between the magnets.

Another sample holder intended for a sample under pressure is illustrated in US published application US2011/0030223. It has a non-magnetic metal tube to retain pressure. The radio-frequency coil required for NMR is located inside this tube, with the sample placed inside the coil. The metal tube and the end pieces screwed into it provide sufficient strength to resist both radially outward stress (hoop stress) and also longitudinal stress resulting from the internal pressure.

### SUMMARY

This summary is provided to introduce a selection of concepts that are further described below. This summary is not intended to be used as an aid in limiting the scope of the subject matter claimed.

One aspect of the subject matter disclosed in this application is apparatus which comprises a nuclear magnetic resonance (NMR) spectrometer including a magnet system providing a magnetic field, at least one coolant vessel containing at least one radiofrequency coil for transmitting and/or receiving electromagnetic radiation, with the at least one coil located within the magnetic field and cooled by coolant in the vessel, and a pressurizable sample holder which comprises a nonmagnetic pressure retaining tube formed of nonmetallic electrically insulating matrix material containing electrically insulating reinforcing filaments, wherein the spectrometer is configured to accommodate the sample holder with the axis of the pressure retaining tube transverse to the magnetic field and with the at least one radiofrequency coil at the exterior of the pressure retaining tube.

Retaining pressure requires mechanical strength and non-metals are usually avoided when strength is required. However, non-metals are generally electrically non-conductive and employing a non-metallic electrically insulating material for the pressure retaining tube avoids unwanted induction of eddy currents in the material of the tube when gradient coils in the NMR spectrometer are switched on and off to superimpose a temporary magnetic field gradient on the main magnetic field of the spectrometer.

Positioning both the sample and pressure containing tube inwardly of the radio-frequency coil or coils gives a low coil filling factor compared to an arrangement with the radio-frequency coil inside the pressure retaining tube. The arrangement disclosed here contrasts with the customary approach of seeking to maximize the coil filling factor in order to maximize in turn the signal to noise ratio of the magnetic resonance signals. Cooling a radio-frequency coil is known to improve the signal to noise ratio and this phenomenon has been used to enhance the quality of weak signals. The arrangement disclosed here utilizes cooling of the radio-frequency coil(s) for a different reason, which is to offset a geometry leading to reduced coil filling factor.

A range of nonmetallic and electrically insulating materials may be used for the pressure retaining tube. One possibility is a ceramic material. Another possibility is an electrically insulating composite comprising an electrically insulating matrix material reinforced with electrically insulating filaments. The matrix may be ceramic or may be an organic polymer. Possibilities for insulating filaments include glass fiber and fibers of poly-paraphenylene terephthalamide—marketed under the trade name Kevlar.

A coolant vessel may be an annular container, for instance a vacuum flask (also termed a Dewar vessel) which is of annular shape. Such an annular container may be positioned in the magnetic field of the NMR spectrometer and encircle a space for the sample holder. The radio-frequency coil or coils cooled within the coolant vessel may be wound as at least one helical solenoid. Other forms of coil may be used: one possibility is a pair of saddle coils, one at each side of the pressure retaining tube. If the coils do not encircle the pressure resistant tube, it is possible that an annular cooling vessel is used, or that some other shape of cooling vessel or vessels is used. One possibility is a pair of saddle coils each contained in a cooling vessel which is half an annulus.

A coolant vessel may simply be a container for a quantity of static coolant placed in it or there may be provisional for circulation of coolant from a supply source through the vessel, for example circulation of coolant from a cryocooler through the vessel or vessels and back to the cryocooler. A description of various types of cryocooler is provided by Radebaugh in Journal of Phyics: Condensed Matter, Vol. 21, 164219 (2009).

The apparatus may include means to maintain the sample within the sample holder at a temperature which is higher than the temperature of the coolant. This may for instance be provision to circulate fluid through a cavity at the interior of the pressure retaining tube of the sample holder.

The sample contained in a sample holder as above may possibly be a liquid, or may be a solid, such as a rock sample which may be a porous rock with liquid in its pores.

In a further aspect, the disclosed subject matter provides a method of examining a sample by NMR comprising placing a sample in a pressurizable sample holder which (as above) comprises a nonmagnetic pressure retaining tube formed of nonmetallic electrically insulating matrix material containing electrically insulating reinforcing filaments; placing the sample holder in an NMR spectrometer including a magnet system providing a magnetic field, such that the axis of the pressure retaining tube is transverse to the magnetic field; providing at least one coolant vessel containing at least one radiofrequency coil at the exterior of the pressure retaining tube; cooling the at least one coil with coolant in the vessel; and applying a radio-frequency signal to a cooled coil within the vessel to induce magnetic resonance of nuclei in the sample, and using the same or another cooled coil within the vessel to receive radio-frequency emissions from the sample.

A sample holder as discussed above may be provided with structural parts to contain pressure longitudinally relative to the tube, these structural parts comprising pieces to apply force longitudinally at the ends of tube and connecting structure extending between these pieces outside the tube.

### BRIEF DESCRIPTION OF THE DRAWINGS

FIG. 1 is a schematic cross-section showing basic parts of a sample holder in the magnetic field of an NMR spectrometer;

FIG. 2 is a cross sectional view on line II-II of FIG. 1;

FIG. 3 is a cross sectional view similar to FIG. 2, but with saddle coils and circulation of coolant; and

FIG. 4 is a schematic cross-section of an example of sample holder able to receive liquid under pressure.

### DETAILED DESCRIPTION

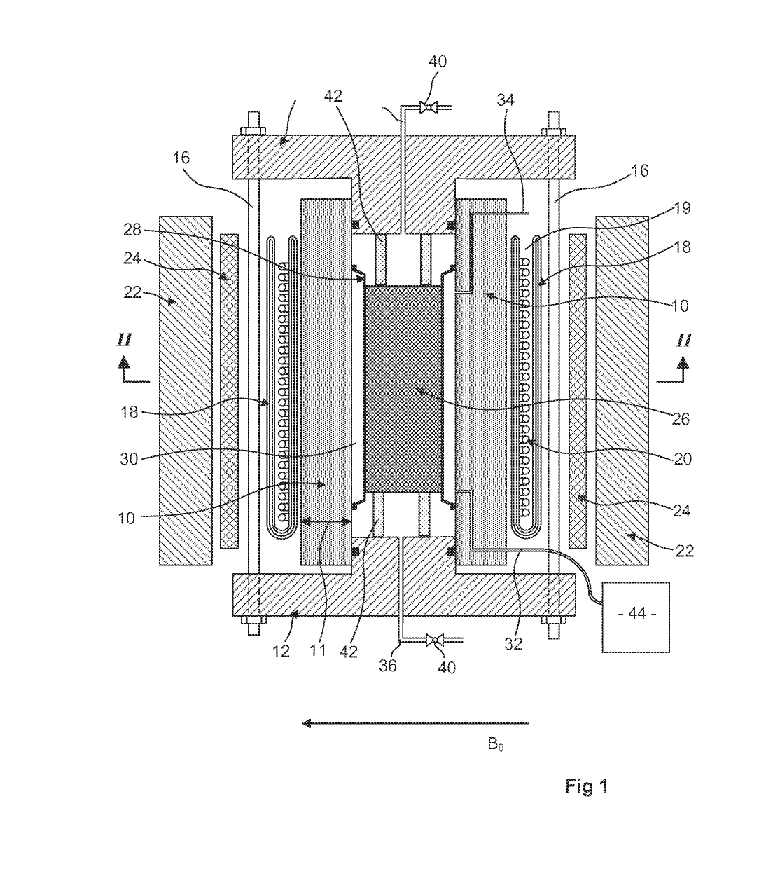

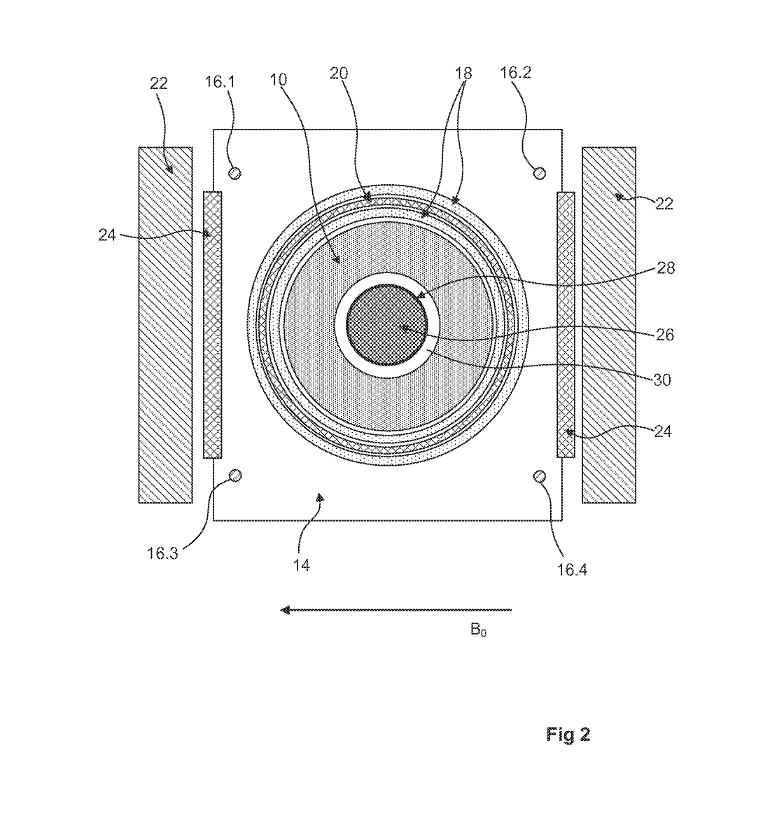

The sample holder shown in FIGS. 1 and 2 has a non-metallic pressure retaining tube 10 with substantial wall thickness, indicated by double headed arrow 11, so as to withstand hoop stress, i.e., radially outward pressure from within. Longitudinal stress from internal pressure is restrained by end pieces 12, 14 which are connected together by a four tie rods 16 which are in tension. Thus the tube 10 is not required to provide longitudinal strength. Both end pieces 12, 14 may be removable and sealed to the tube by O-rings as shown or the tube 10 could be permanently attached to one of the end pieces.

A number of non-metallic materials can be used for the tube 10. One possibility is an inorganic ceramic material. Another possibility is a fiber-reinforced composite in which elongate fibers are bound in a matrix material which may be an inorganic ceramic or may be an organic polymer. Glass reinforced polymer (GRP) is a well-known example of composite material. An organic polymer used as the matrix of a composite material may be any of a number of polymers including epoxy resin and polyetherether ketone (PEEK) which is well established as an engineering plastic.

The pressure retaining tube 10 of the sample holder is encircled by a vessel 18 to contain coolant. The vessel is a vacuum flask, often referred to as a Dewar flask. It has double walls with vacuum between the two walls. This vessel 18 is annular in shape so that the space for coolant is an annulus open at its top 19 allowing coolant to be poured in. A radio-frequency coil 20 is located within this annulus and so it will be immersed in the coolant. The coolant may be liquid nitrogen so as to cool the coil 20 to 77K (−196° C.) which is the boiling temperature of nitrogen. The double walls of vessel 18 are shown in FIG. 1, but for the sake of simplicity, FIG. 2 merely shows the inner and outer walls of the vessel 18.

The coil 20 is shown schematically as a single helical solenoid coil but it may be wound with multiple layers. It is possible that there could be more one coil, for example one coil as an emitter and one as an antenna with the two coils wound one on top of the other and both immersed in the coolant.

The NMR spectrometer has a pair of disc shaped permanent magnets 22 facing each other but spaced apart so that a magnetic field extends in the direction indicated by the arrow B₀. Both permanent magnets 22 may be made of rare earth compounds to give a high magnetic field. Specifically, they may possibly be neodymium iron boron (NdFeB) magnets which can be manufactured in the desired shapes or assembled from smaller blocks.

Gradient coils 24 are positioned adjacent the magnets 22. When these gradient coils 24 are energised, a magnetic field with a gradient along the length of these coils, which is the vertical direction as seen in FIG. 1, superimposed on the static field B₀. This field gradient is proportional to the current in the coils 24 and its magnitude can thus be controlled.

The coolant vessel 18 and the pressure retaining tube 10 of the sample holder are positioned in the magnetic field between the gradient coils 24. As best seen from FIG. 2, the tie rods 16 at either side of the tube 10 are then located at positions which are spaced laterally from the axis of tube 10.

FIG. 2 shows that the geometry can be fairly compact. The four tie rods 16, which are indicated as 16.1 to 16.4 in FIG. 2, are at a radial distance from the axis of tube 10 which is approximately twice the external radius of the pressure retaining tube 10 and approximately the same as the distance from the tube axis to the magnets 22. The tie rods 16.1 and 16.2 are spaced from the axis of the tube 10 and from the tie rods 16.3 and 16.4 in directions transverse to the magnetic field B₀. The spacing between the tie rods 16.1 and 16.3 is equal to spacing between rods 16.2 and 16.4, and is less than double the external diameter of the tube 10. The spacing in the direction of the magnetic field B₀ between the tie rods 16.1 and 16.2 is equal to spacing between rods 16.3 and 16.4. It is less than the spacing between the magnets 22 and again it is less than twice the external diameter of the tube 10.

A rock sample 26 is located within the tube 10. The end faces of the sample 26 are exposed but the cylindrical surface of the sample is enclosed and sealed by an elastomeric sleeve 28. This sleeve 28 is urged against the cylindrical surface of the sample 26 by a liquid, referred to as confining fluid, in the space 30 between the sleeve 28 and the inside wall of tube 10. This confining fluid may be a perfluorocarbon which does not contain hydrogen atoms and does not give any signal when NMR is used to examine resonance of hydrogen nuclei. The space 30 between the sleeve 28 and the inside wall of tube 10 is connected to inlet and outlet pipes 32, 34 by passages through the wall of tube 10.

Fluid to pressurize the interior of the tube 10 can be introduced along passages 36 and 38 which extend through the end members 12 and 14. These passages can be closed by valves 40. It is also possible to flow fluid linearly through the sample 26, using passage 36 as an inlet for fluid under pressure while maintaining a slightly lower pressure in passage 38 as outlet. At least one spacer piece 42, made of non-magnetic and electrically insulating material is used to keep the sample 26 in position. Such a spacer piece 42 may be made of a porous material or may incorporate apertures, to allow the end faces of the sample 26 to communicate with the passages 36, 38.

The confining fluid in the space 30 may be at the same pressure as fluid entering the interior of tube 10 along passage 34, or may be at a slightly higher pressure. The confining fluid may also be circulated to control temperature, being supplied from a temperature-controlled reservoir diagrammatically indicated at 44 to inlet pipe 32, thus maintaining the sample 26 at the temperature of the circulating confining fluid. Fluid from outlet pipe 34 flows back to the reservoir 44 by a return pipe which is not shown.

The following calculation shows that cooling can offset a low coil filling factor. If the radio-frequency coil is a helical solenoid, the signal to noise ratio in an NMR measurement is given by the following equation, initially set out by Hoult and Richards in “The signal-to-noise ratio of the Nuclear Magnetic Resonance experiment,” J. Magnetic Resonance, vol. 24, pp. 71-85, 1976.

$$SNR = \frac{{K ( {B}_{1} )}_{xy} {V}_{s} N γ {ℏ}^{2} I ( I + 1 )}{7.12 k {T}_{s}} \cdot {( \frac{p}{{FkT}_{c} 𝓁ζΔ f} )}^{1 / 2} \cdot \frac{{ω}_{0}^{7 / 4}}{{\{ {μμ}_{0} ρ ( {T}_{c} ) \}}^{1 / 4}} \qquad ( 1 )$$

In this formula, fundamental constants have their usual notation, viz.

h is Planck's constant divided by 2π,

k is Boltzmann's constant,

μ₀=4π×10-7 Hm⁻¹ and is the permeability of free space,

γ is the magnetogyric ratio of the resonant nucleus (¹H in the present context) and

I is the nuclear spin quantum number (I=½ for ¹H).

The resonant (angular) frequency of the nucleus is denoted by ω₀. Absolute temperatures are denoted by T_{S} for the sample and by T_{C} for the coil; note that in the present discussion these temperatures may be radically different. Characteristics of the sample are its volume V_{S}, and the number density N of its resonant species. Properties of the spectrometer's pre-amplifier are F, the Noise Figure, and Δf, the bandwidth of the resonant circuit. Properties of the coil itself are its winding length l, the perimeter p of the wire used, its magnetic relative permeability μ, (essentially μ=1 for copper), and its electrical resistivity ρ(T_{C}), at the temperature T_{C} of the coil. A so-called “proximity” factor ζ is included which accounts for the current flowing in neighbouring coil windings when calculating the distribution of current actually flowing within the wire cross section. Finally, the overall winding geometry is implicitly included in the factor (B₁)_{xy} which denotes the magnetic field over the sample produced by unit current in the coil. Where B is inhomogeneous then this can be taken into account by the “inhomogeneity factor” K. For a solenoid, K=1 can be taken as a reasonable approximation, so this will not be considered further.

The physical basis of the above formula takes into account:
1. the induced e.m.f. by precessing nuclear magnetization;
2. the magnitude of such nuclear magnetization at thermal equilibrium;
3. the electrical noise arising from thermal reasons within the coil conductor, according to the well-known formula for “Johnson noise”; and
4. the skin depth for the r. f, current flowing in the wire of the coil.

The coil filling factor does not appear explicitly in formula (1) above because the coil volume itself does not appear as a parameter. However, the result is consistent with the filling factor criterion in that the SNR is directly proportional to sample volume V_{S}.

The factors (B₁)_{xy} and K can both be calculated from first principles of magnetostatics (e.g., the Biot-Savart law), given the coil geometry. The result given by Hoult and Richards for the B₁ field at the centre of the sample is

$${( {B}_{1} )}_{xy} = \frac{{μ}_{0} n}{2} \frac{1}{{[ {a}^{2} + {g}^{2} ]}^{1 / 2}} \qquad ( 2 )$$

for a solenoid of n turns, radius a and length 2g.

Using these formulae we can state a ratio of the SNR values obtained from two coils at different temperatures, used for the same sample volume V_{S}. We will assume that we detect the same resonance, with a pre-amplifier of the same Noise Figure F and receiver bandwidth Δf. Then a ratio of the respective SNR values given by formula (1) is

$$\frac{{SNR}_{1}}{{SNR}_{2}} = \frac{{( {B}_{1} )}_{xy} ( 1 )}{{( {B}_{1} )}_{xy} ( 2 )} {( \frac{{p}_{1} {𝓁}_{2} {ζ}_{2} {T}_{c 2}}{{p}_{2} {𝓁}_{1} {ζ}_{1} {T}_{c 1}} )}^{1 / 2} {( \frac{{ρ}_{2} ( {T}_{c 2} )}{{ρ}_{1} ( {T}_{c 1} )} )}^{1 / 4}$$

Employing further the solenoid field calculation in formula (2), and approximating the winding length i as 2πan where (as above) a is the coil radius and n is the number of turns, we obtain

$$\frac{{SNR}_{1}}{{SNR}_{2}} = {[ \frac{{a}_{2}^{2} + {g}_{2}^{2}}{{a}_{1}^{2} + {g}_{1}^{2}} ]}^{1 / 2} {( \frac{{p}_{1} {a}_{2} {n}_{1} {ζ}_{2} {T}_{c 2}}{{p}_{2} {a}_{1} {n}_{2} {ζ}_{1} {T}_{c 1}} )}^{1 / 2} {( \frac{{ρ}_{2} ( {T}_{c 2} )}{{ρ}_{1} ( {T}_{c 1} )} )}^{1 / 4} \qquad ( 4 )$$

We now suppose that coil (1) is a cooled coil outside the pressure retaining tube 10 of the sample holder and coil (2) is a coil only slightly larger than a cylindrical sample, such as a coil inside a pressure retaining tube, so as to have a high coil filling factor. Such a coil will be at the sample temperature so that T_{c2}=T_{S} We also assume that the two coils have the same aspect ratio, wire diameter and number of turns of the coil, with similar proximity factors. The formula simplifies as follows:

$$\frac{{SNR}_{1}}{{SNR}_{2}} = {( \frac{{a}_{2}}{{a}_{1}} )}^{3 / 2} {( \frac{{T}_{s}}{{T}_{c}} )}^{1 / 2} {( \frac{ρ ( {T}_{s} )}{ρ ( {T}_{c} )} )}^{1 / 4} \qquad ( 5 )$$

Copper has a linear variation of resistivity with temperature down to about 75K with a temperature coefficient of resistivity of about 0.004 deg⁻¹. This is consistent with the Debye model for lattice vibrational modes (phonons) which are the limiting factor in electrical conduction in metals. Because ρ(T) varies linearly with temperature down to liquid nitrogen temperatures, the formula (5) above simplifies further to a very simple estimator:

$$\frac{{SNR}_{1}}{{SNR}_{2}} \approx {( \frac{{a}_{2}}{{a}_{1}} )}^{3 / 2} {( \frac{{T}_{s}}{{T}_{c}} )}^{3 / 4} \{ 7 ) \qquad ( 6 )$$

In circumstances where the signal to noise ratios SNR₁ and SNR₂ are equal, the formula becomes

$$1 = {( \frac{{a}_{2}}{{a}_{1}} )}^{3 / 2} {( \frac{{T}_{s}}{{T}_{c}} )}^{3 / 4} \qquad ( 7 )$$

Then raising this to the power of ⅔ gives:

$$\frac{{a}_{1}}{{a}_{2}} = {( \frac{{T}_{s}}{{T}_{c}} )}^{1 / 2} \qquad ( 8 )$$

This allows us to estimate the diameter of a coil (1) chilled to liquid nitrogen temperature which will give the same signal to noise ratio as the coil (2) above which is at ambient temperature and only slightly larger than a rock sample. Assume that coil (2) has a diameter of 40 mm (to accommodate a 38 mm core plug) and is at a sample temperature of 30° C.=303K. Assume also that the temperature of the cooled coil (1) is that of boiling nitrogen, i.e., 77K.

By substituting these values in the formula above, it is found that a coil (1) at liquid nitrogen temperature with a diameter of 80 mm will give the same signal to noise ratio as a coil (2) with a diameter of 40 mm at 30° C. when the sample is the same in both cases.

Of course, it is possible that a sample could be at a somewhat higher temperature, perhaps up to 130° C.=403K. It is possible also that the cooled coil could be at some other temperature, possibly lower than that of boiling nitrogen. At temperatures below that of boiling nitrogen copper displays a variation of resistivity with temperature which is no longer linear. This enhances the benefit of cooling the coil and it may therefore be beneficial to cool the radio-frequency coil(s) to around 20K (−253° C.) using helium gas from a cryocooler as the coolant.

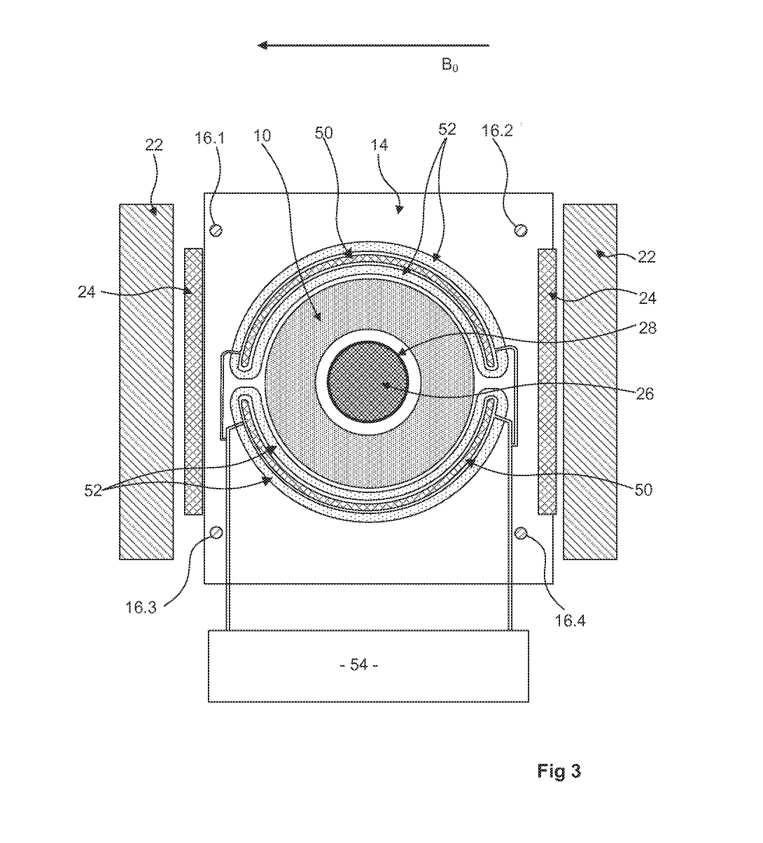

FIG. 3 shows a variation of the arrangement of FIGS. 1 and 2. In place of the helical solenoid as radio-frequency coil there are a pair of saddle coils 50 each in a vacuum flask 52 which is half an annulus. These vacuum flasks are closed vessels (unlike the open topped vacuum flask shown in FIGS. 1 and 2) and coolant is circulated through both of them from a cryocooler diagrammatically indicated at 54.

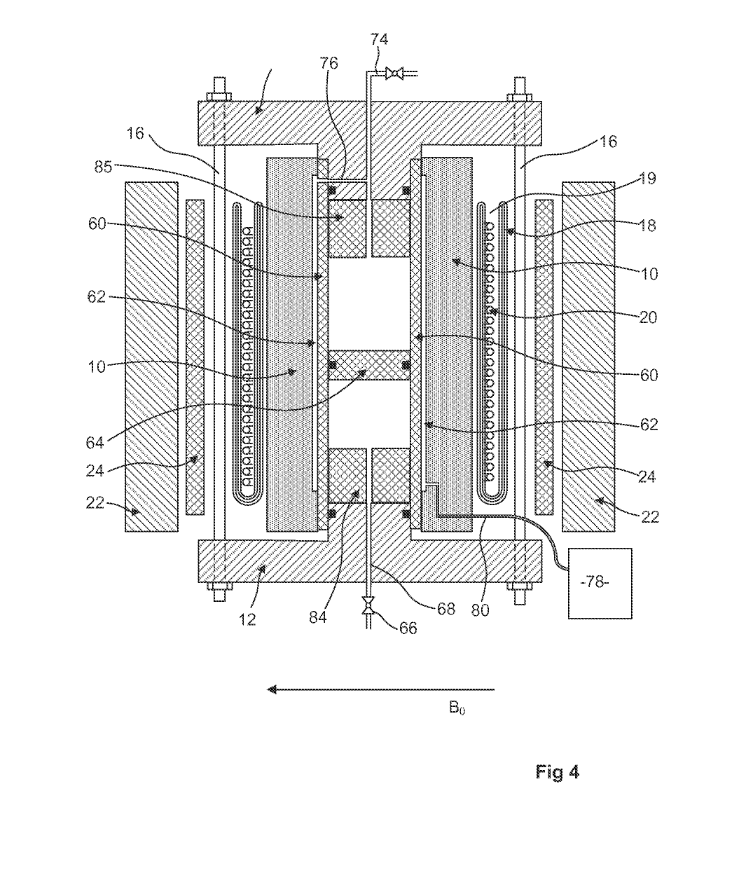

FIG. 4 shows a sample holder for a liquid sample which is required to be kept under pressure. The general arrangement has similarity to that in FIGS. 1 and 2. A pressure retaining tube 10 contains hoop stress, while longitudinal stress is contained by end members 12, 14 connected by tie rods 16 which are in tension. Inside the pressure-retaining tube 10 there is a tube 60 made of an inorganic ceramic material. This is non-magnetic, electrically insulating and stable in contact with hydrocarbon. A suitable material is magnesia stabilized zirconia. Dynamic-Ceramic Ltd of Crewe, UK supplies this under the name Technox 300 as a raw material for fabricating ceramic articles. This tube 60 has thinner walls than the pressure retaining tube 10. In this embodiment, the tube 10 is shaped to create an annular cavity 62 between the vessel 60 and the tube 10.

In order to admit a sample fluid under pressure, the tube 60 encloses an internal floating piston 64. The sample fluid is admitted under pressure through valve 66 and along line 68 to the chamber 70 at one side of the piston 64 while the chamber 72 at the other side of floating piston 64 is pressurized with fluid supplied along line 74. This fluid may be a perfluorocarbon so that it does not contain hydrogen atoms. The pressure in chamber 72 is reduced to slightly less than the pressure of the incoming sample entering through inlet 68, so that the incoming sample slowly drives the piston 64 along the vessel 60, expelling fluid along line 74 until vessel 60 is filled with the sample fluid.

The cavity 62 is connected by passage 76 to the line 74 and hence to the chamber 72. After the sample fluid has been admitted to chamber 70, the fluid pressure in line 74 and cavity 62 is maintained at slightly less than the pressure in chamber 70. Thus pressure inside the tube 60 is almost balanced by a pressure in the cavity 62 around the exterior of the tube 60 and this avoids subjecting tube 60 to too much hoop stress. The fluid in cavity 62 is kept circulating under pressure. Fluid from a temperature controlled reservoir 78 is supplied to cavity 62 along line 80 and returns to the reservoir 78 after leaving along line 74 (the return path is not shown).

Within the tube 60 there are end pieces 84, 85 which occupy space at each end of the interior of tube 60. When the sample has been introduced through line 68 and the floating piston 64 has been driven fully along the tube 60 so that it abuts end piece 85, the volume occupied by the sample is in a middle part of the length of coil 20. Consequently the liquid sample is spaced from any distortions of the radio-frequency field near the ends of the coil 20.

It will be appreciated that the example embodiments described in detail above can be modified and varied within the scope of the concepts which they exemplify. Features referred to above or shown in individual embodiments above may be used together in any combination as well as those which have been shown and described specifically. Accordingly, all such modifications are intended to be included within the scope of this disclosure as defined in the following claims.

1. Apparatus for examination of a sample under pressure, comprising:
a nuclear magnetic resonance (NMR) spectrometer including a magnet system providing a magnetic field;
at least one coolant vessel containing at least one radiofrequency coil for transmitting and/or receiving electromagnetic radiation, with the at least one coil located within the magnetic field and cooled by coolant in the vessel; and
a pressurizable sample holder which comprises a nonmagnetic pressure retaining tube formed of nonmetallic electrically insulating matrix material containing electrically insulating reinforcing filaments,
wherein the spectrometer is configured to accommodate the sample holder with the axis of the pressure retaining tube transverse to the magnetic field, and the at least one radiofrequency coil at the exterior of the pressure retaining tube.

2. Apparatus according to claim 1, wherein the coolant vessel is annular, and the spectrometer is configured to receive the sample holder within space encircled by the annular coolant vessel.

3. Apparatus according to claim 2, wherein the at least one coil is at least one helically wound solenoid and the spectrometer is configured to receive the sample holder within the coolant vessel and coaxial with the at least one coil.

4. Apparatus according to claim 1, wherein the at least one coil is at least one pair of saddle coils and the spectrometer is configured to accommodate the sample holder between the saddle coils.

5. Apparatus according to claim 1, further comprising means to circulate coolant through the coolant vessel.

6. Apparatus according to claim 1, comprising means to circulate fluid through the sample holder to control the temperature within the sample holder.

7. Apparatus according to claim 1, wherein the matrix material of the pressure retaining tube is an organic polymer.

8. Apparatus according to claim 1, further comprising end pieces to apply force longitudinally at the ends of the pressure retaining tube and connecting structure extending between these end pieces outside the pressure retaining tube.

9. Apparatus according to claim 8, wherein the connecting structure lies within a circular cross section which is not more than twice the diameter of the pressure retaining tube.

10. Apparatus according to claim 1, wherein the pressure retaining tube surrounds an electrically insulating tube to contain a liquid sample.

11. Apparatus according to claim 10, wherein the tube for the liquid sample contains a movable piston to separate the sample from a pressure controlling liquid maintained under pressure as the sample enters the tube at a higher pressure.

12. Apparatus according to claim 11, wherein a space between the pressure retaining tube and the tube for the liquid sample is in pressure communication with the pressure controlling liquid.

13. Apparatus according to claim 12, comprising means to circulate a temperature control fluid through the space to control the temperature of the liquid sample.

14. A method of examining a sample by NMR comprising:
placing a sample in a pressurizable sample holder which comprises a nonmagnetic pressure retaining tube formed of nonmetallic electrically insulating matrix material containing electrically insulating reinforcing filaments;
placing the sample holder in an NMR spectrometer including a magnet system providing a magnetic field, such that the axis of the pressure retaining tube is transverse to the magnetic field;
providing at least one coolant vessel containing at least one radiofrequency coil at the exterior of the pressure retaining tube;
cooling the at least one coil with coolant in the vessel; and
applying a radio-frequency signal to a cooled coil within the vessel to induce magnetic resonance of nuclei in the sample, and using the same or another cooled coil within the vessel to receive radio-frequency emissions from the sample.
